(19) United States
(12) Patent Application Publication
(10) Pub. No.: US 2011/0287629 A1
(43) Pub. Date: Nov. 24, 2011

(54) SILICON FILM FORMATION METHOD AND SILICON FILM FORMATION APPARATUS

(75) Inventors: Akinobu KAKIMOTO, Nirasaki City (JP); Satoshi TAKAGI, Nirasaki City (JP); Jyunji ARIGA, Nirasaki City (JP); Norifumi KIMURA, Nirasaki City (JP); Kazuhide HASEBE, Nirasaki City (JP)

(73) Assignee: TOKYO ELECTRON LIMITED, Tokyo (JP)

(21) Appl. No.: 13/110,333

(22) Filed: May 18, 2011

(30) Foreign Application Priority Data
May 20, 2010 (JP) 2010-116344
Apr. 19, 2011 (JP) 2011-093279

(51) Int. Cl. H01L 21/285; H01L 21/306

(52) U.S. Cl. 438/652; 156/345.31; 156/345.24; 257/E21.16

(57) ABSTRACT

A silicon film formation method includes a first film formation operation, an etching operation, and a second film formation operation. In the first film formation operation, a first silicon film is formed to fill the groove of the object to be processed. In the etching operation, an opening of the groove is widened by etching the first silicon film formed in the first film formation operation. In the second film formation operation, a second silicon film is formed on the groove having the opening widened in the etching operation to fill the groove. Accordingly, a silicon film is formed on a groove of an object to be processed having the groove provided thereon.

### CROSS-REFERENCE TO RELATED PATENT APPLICATIONS

This application claims the benefits of Japanese Patent Application No. 2010-116344, filed on May 20, 2010 and Japanese Patent Application No. 2011-093279, filed on Apr. 19, 2011 in the Japan Patent Office, the disclosures of which are incorporated herein in its entirety by reference.

### BACKGROUND OF THE INVENTION

1. Field of the Invention

The present invention relates to a silicon film formation method and a silicon film formation apparatus.

2. Description of the Related Art

Processes for manufacturing semiconductor devices or the like include an operation for manufacturing an electrode by forming a trench and a hole type groove (contact hole) on an interlayer insulation layer on a silicon substrate and filling the trench and the hole type groove with a silicon film (Si film), such as a polysilicon film, an amorphous silicon film, a polysilicon film doped with impurities, and an amorphous silicon film doped with impurities, or the like.

In such an operation, as disclosed in the patent reference 1, for example, a contact hole is provided on an interlayer insulation layer on a silicon substrate, a polysilicon is formed thereon, the polysilicon is slightly etched, and a polysilicon is formed again by using a CVD (Chemical Vapor Deposition) method.

3. Prior Art Reference
(Patent Reference 1) Japanese Patent Laid-Open Publication No. hei 10-321556

### SUMMARY OF THE INVENTION

However, due to miniaturization of semiconductor devices, an aspect ratio of a groove to be filled with a Si film is high. If an aspect ratio increases, a void may easily occur during filling the groove with a Si film, and thus properties of the Si film as an electrode can be deteriorated. Therefore, there is a demand for a Si film formation method, by which occurrence of a void may be suppressed even if an aspect ratio increases.

To solve the above problems, the present invention provides a Si film formation method and a Si film formation apparatus, by which occurrence of a void may be suppressed.

According to an aspect of the present invention, there is provided a silicon film formation method for forming a silicon film on a groove of an object to be processed, the groove being provided on a surface of the object to be processed, the silicon film formation method including forming a first silicon film to fill the groove of the object to be processed etching the first silicon film formed in the forming the first silicon film to widen an opening of the groove; and forming a second silicon film on the groove having the opening widened in the etching the first silicon film to fill the groove.

According to another aspect of the present invention, there is provided a silicon film formation apparatus for forming a silicon film on a groove of an object to be processed, the groove being provided on a surface of the object to be processed, the silicon film formation apparatus including a first film formation unit which forms a first silicon film to fill the groove of the object to be processed; an etching unit which etches the first silicon film formed by the first film formation unit to widen an opening of the groove; and a second film formation unit which forms a second silicon film on the groove having the opening widened by the etching unit to fill the groove.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram of a heat treatment apparatus according to an embodiment of the present invention;

FIG. 2 is a diagram showing the configuration of a controller of FIG. 1;

FIG. 3 is a diagram showing a recipe describing a silicon film formation method according to the present embodiment;

FIGS. 4A through 4D are diagrams for describing the silicon film formation method according to the present embodiment;

FIG. 5A is a diagram showing conditions for forming a silicon film, and FIG. 5B is a diagram showing void rate;

FIG. 6 is a diagram showing a recipe describing a silicon film formation method according to another embodiment of the present invention;

FIGS. 7A through 7E are diagrams for describing the silicon film formation method according to another embodiment of the present invention; and

FIG. 8 is a diagram showing a recipe describing a silicon film formation method according to another embodiment of the present invention.

### DETAILED DESCRIPTION OF THE INVENTION

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

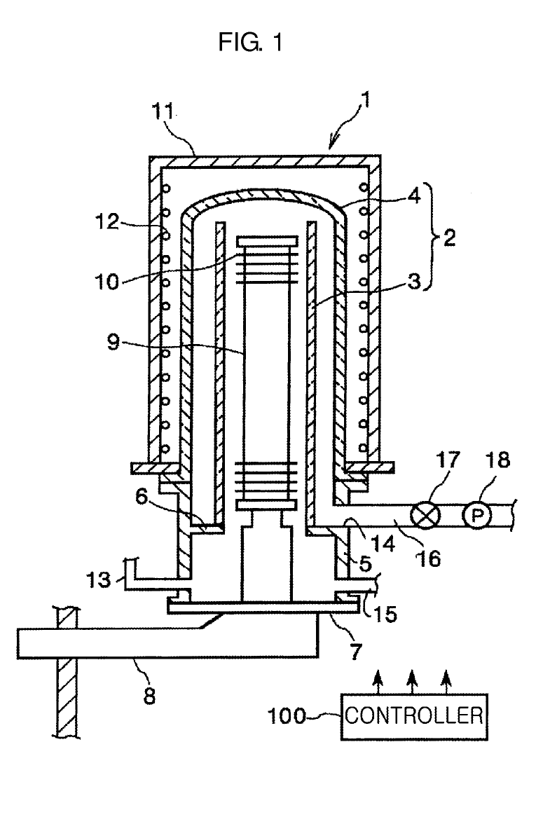

Hereinafter, a silicon film formation method and a silicon film formation apparatus according to the present invention will be described. A case in which a batch type and vertical heat treatment apparatus of FIG. 1 is used as a silicon film formation apparatus will be described as an example.

As shown in FIG. 1, a heat treatment apparatus 1 includes a substantially cylindrical reaction pipe 2, of which a lengthwise direction is parallel to a vertical direction. The reaction pipe 2 has a double pipe structure including an inner pipe 3 and an outer pipe 4, which covers the inner pipe 3, has a ceiling, and is arranged to be a constant distance apart from the inner pipe 3. The inner pipe 3 and the outer pipe 4 are formed of a material with excellent heat resistance and corrosion resistance, for example, quartz.

A manifold 5, which is formed of a stainless steel (SUS) and has a cylindrical shape, is arranged below the outer pipe 4. The manifold 5 is connected to a bottom end of the outer pipe 4 in an airtight manner. Furthermore, the inner pipe 3 is supported by a supporting ring 6, which protrudes from an inner wall of the manifold 5 and is provided as a single body with the manifold 5.

A cover 7 is arranged below the manifold 5, and the cover 7 may be moved up and down by a boat elevator 8. Furthermore, the bottom of the manifold 5 (inlet of a furnace) is closed when the cover 7 is moved upward by the boat elevator 8, whereas the bottom of the manifold 5 (inlet of the furnace) is opened when the cover 7 is moved downward by the boat elevator 8.

A wafer boat 9, which is formed of quartz, for example, is arranged on the cover 7. The wafer boat 9 is configured to be able to hold a plurality of objects to be processed (e.g., semiconductor wafers 10) thereon in a vertical direction of the wafer boat 9 by interposing a predetermined distance between the objects to be processed.

Around the reaction pipe 2, a heat insulator 11 is provided to surround the reaction pipe 2. Heaters 12, which include resistance heat generators, for example, are installed on an inner wall of the heat insulator 11. An interior of the reaction pipe 2 is heated to a predetermined temperature by the heaters 12, and thus the semiconductor wafers 10 are heated to the predetermined temperature.

A plurality of process gas introduction pipes 13 penetrate through (are connected to) a side surface of the manifold 5. Furthermore, FIG. 1 shows only one process gas introduction pipe 13. The process gas introduction pipe 13 is arranged to face an interior of the inner pipe 3. For example, as shown in FIG. 1, the process gas introduction pipe 13 penetrates through the side surface of the manifold 5 below the supporting ring 6 (below the inner pipe 3).

A process gas supply source is connected to the process gas introduction pipe 13 via a mass flow controller (not shown) or the like. Therefore, a desired amount of a process gas is supplied from the process gas supply source into the reaction pipe 2 via the process gas introduction pipe 13. Process gases supplied from the process gas introduction pipe 13 include film formation gases for forming silicon films (Si films), such as a polysilicon film, an amorphous silicon film, a polysilicon film doped with impurities, and an amorphous silicon film doped with impurities, or the like. SiH₄ or the like may be used as the film formation gas. Furthermore, the impurities such as PH₃, BCl₃, or the like may be included in the film formation gas in a case where Si film is doped with the impurities.

Furthermore, in a silicon film formation method according to the present invention, as described later, a groove provided on the surface of the semiconductor wafers 10 is filled with a Si film (a first Si film) in a first film formation operation, an opening of the filled groove is widened in an etching operation, and the groove having the widened opening is filled with a Si film (a second Si film) in a second film formation operation. Therefore, process gases supplied from the process gas introduction pipe 13 include an etching gas. For example, a halogen gas, such as Cl₂, F₂, ClF₃, or the like, is used as an etching gas.

Furthermore, in a silicon film formation method according to the present invention, as described later, in a case of forming a seed layer on a groove prior to the first film formation operation, a gas for forming the seed layer, for example, silane including amino groups or a high order silane including Si₂H₆, Si₄H₁₀ or the like, is supplied from the process gas introduction pipe 13 into the reaction pipe 2. Examples of silane including amino groups are bis(tertiary butylamino)silane (BTBAS), tri(di methylamino)silane (3DMAS), tetra(dimethylamino)silane (4DMAS), diisopropylaminosilane (DIPAS), bis(diethylamino)silane (BDEAS), bis(dimethylamino)silane (BDMAS), or the like. Furthermore, in the silicon film formation method, as described later, in a case of removing a natural oxide film from a groove prior to the first film formation operation, gases for removing a natural oxide film, for example, ammonia and HF, or ammonia and NF₃, are simultaneously supplied into the reaction pipe 2 from the process gas introduction pipe 13.

An exhaust port 14 for evacuating a gas inside the reaction pipe 2 is provided on the side surface of the manifold 5. The exhaust port 14 is provided above the supporting ring 6, and thus the exhaust port 14 communicates with a space formed between the inner pipe 3 and the outer pipe 4 in the reaction pipe 2. Furthermore, an exhaustion gas or the like produced from the inner pipe 3 passes through the space between the inner pipe 3 and the outer pipe 4 and is evacuated via the exhaust port 14.

A purge gas supply pipe 15 penetrates through a portion of the side surface of the manifold 5 below the exhaust port 14. A purge gas supply source (not shown) is connected to the purge gas supply pipe 15, and thus a desired amount of a purge gas, for example, nitrogen gas, is supplied from the purge gas supply source into the reaction pipe 2 via the purge gas supply pipe 15.

An exhaust pipe 16 is connected to the exhaust port 14 in an airtight manner. A valve 17 and a vacuum pump 18 are installed on the exhaust pipe 16 in the order stated from an upper side of the exhaust pipe 16. The valve 17 controls a pressure inside the reaction pipe 2 to a predetermined pressure by adjusting an opening degree of the exhaust pipe 16. The vacuum pump 18 evacuates a gas inside the reaction pipe 2 via the exhaust pipe 16 and adjusts the pressure inside the reaction pipe 2 at the same time.

Furthermore, a trap, a scrubber, or the like (not shown) is installed on the exhaust pipe 16, so that an exhaustion gas evacuated from the reaction pipe 2 is purified and harmless and the purified and harmless gas is evacuated out of the heat treatment apparatus 1.

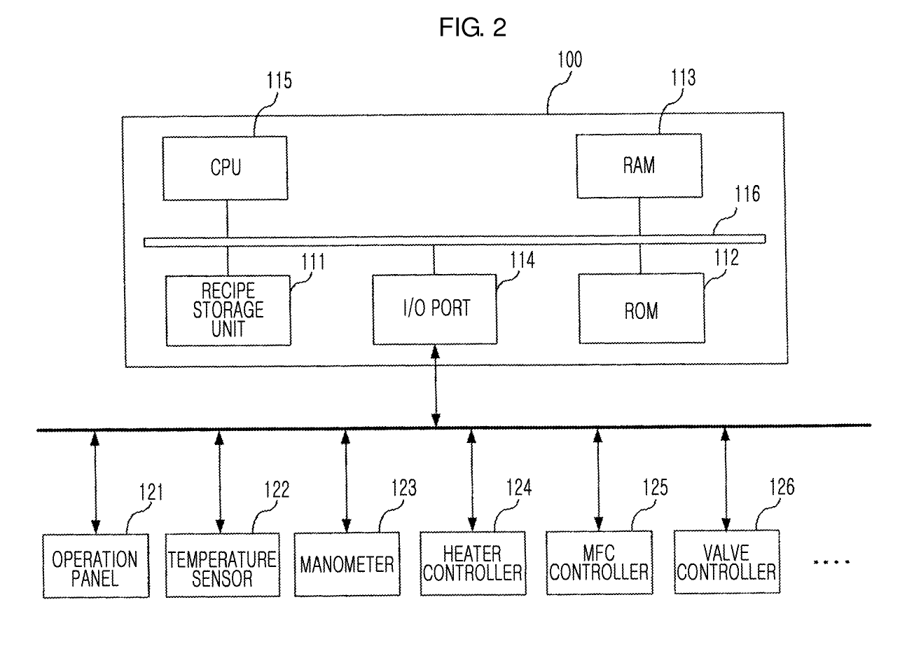

Furthermore, the heat treatment apparatus 1 includes a controller 100 controlling each of the components of the heat treatment apparatus 1. The configuration of the controller 100 is shown in FIG. 2. As shown in FIG. 2, an operation panel 121, a temperature sensor (group) 122, a manometer (group) 123, a heater controller 124, a MFC controller 125, a valve controller 126, or the like is connected to the controller 100.

The operation panel 121 includes a display screen and operation buttons, transmits an operation instruction of an operator to the controller 100, and displays various pieces of information from the controller 100 on the display screen.

The temperature sensor (group) 122 measures temperatures of the respective components, including a temperature inside the reaction pipe 2, a temperature inside the process gas introduction pipe 13, a temperature inside the exhaust pipe 16, or the like, and notifies the measured temperatures to the controller 100.

The manometer (group) 123 measures pressures of the respective components, including a pressure inside the reaction pipe 2, a pressure inside the process gas introduction pipe 13, a pressure inside the exhaust pipe 16, or the like, and notifies the measured pressures to the controller 100.

The heater controller 124 is a unit for independently controlling the heaters 12. The heat controller 124 heats the heaters 12 by applying electricity thereto in response to an instruction from the controller 100, independently measures power consumed by each of the heaters 12, and notifies results of the measurement to the controller 100.

The MFC controller 125 controls mass flow controllers (MFC) (not shown) installed on the process gas introduction pipe 13 and the purge gas supply pipe 15 to adjust flow rates of gases flowing therein to amounts instructed by the controller 100, measures flow rates of gases actually flowing therein, and notifies the measured flow rates to the controller 100.

The valve controller 126 controls respective opening degrees of valves arranged on each of pipes to opening degrees instructed by the controller 100.

The controller 100 includes a recipe storage unit 111, a ROM 112, a RAM 113, an I/O port 114, a CPU (Central Processing Unit) 115, and a bus 116 for interconnecting these elements.

The recipe storage unit 111 stores a setup recipe and a plurality of process recipes. When the heat treatment apparatus 1 is initially manufactured, only a setup recipe is stored therein. A setup recipe is executed for generating heat models corresponding to each of heat treatment apparatuses. A process recipe is a recipe prepared for each of heat treatments (processes) actually performed by a user. For example, a process recipe defines factors, such as changes of temperatures of the respective components, a change of pressure inside the reaction pipe 2, timings to start and stop supplying process gases, amounts of the process gases to be supplied, or the like, from a time point at which the semiconductor wafers 10 are loaded into the reaction pipe 2 to a time point at which the semiconductor wafers 10 are processed and unloaded from the reaction pipe 2.

The ROM 112 includes an EEPROM, a flash memory, a hard disk, or the like, and is a storage medium for storing an operation program or the like of the CPU 115.

The RAM 113 functions as a work area or the like of the CPU 115.

The I/O port 114 is connected to the operation panel 121, the temperature sensor 122, the manometer 123, the heater controller 124, the MFC controller 125, the valve controller 126, or the like and controls input and output of data or signals.

The CPU 115 constitutes a core of the controller 100, and executes a control program stored in the ROM 112 in order to control operations of the heat treatment apparatus 1 according to a recipe (a process recipe) stored in the recipe storage unit 111 in response to instructions from the operation panel 121. In other words, the CPU 115 instructs the temperature sensor (group) 122, the manometer (group) 123, the MFC controller 125, or the like to measure temperatures, pressures, flow rates of gases, or the like inside the respective components including the reaction pipe 2, the process gas introduction pipe 13, and the exhaust pipe 16, outputs control signals or the like to the heater controller 124, the MFC controller 125, the valve controller 126, or the like based on the measured data, and controls each of these components such that it operates according to a process recipe.

The buses 116 deliver data between each of components.

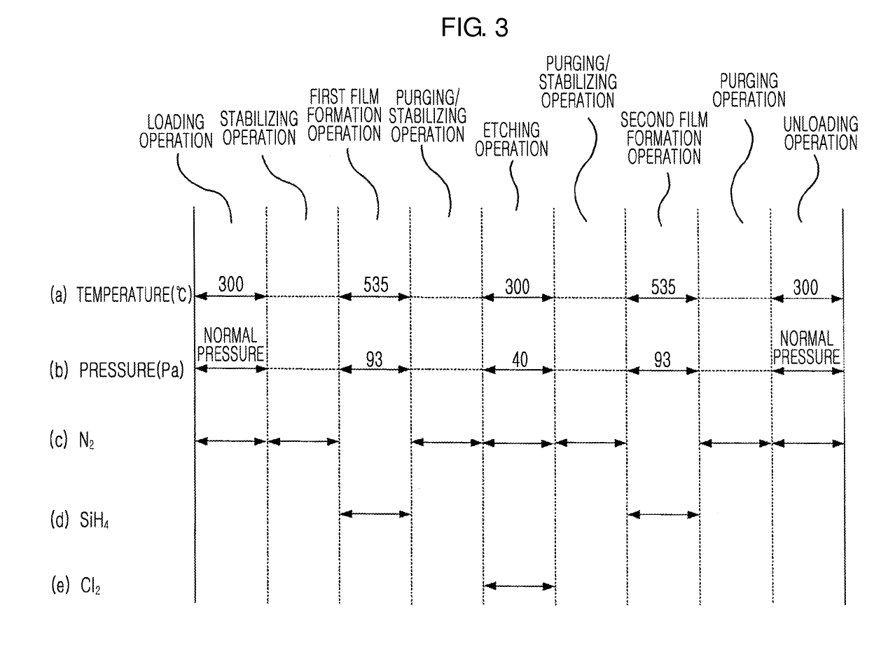

Next, a silicon film formation method by using the heat treatment apparatus 1 configured as described above will be described. Furthermore, in the descriptions below, operations of each of the components constituting the heat treatment apparatus 1 are controlled by the controller 100 (the CPU 115). Furthermore, as described above, temperatures, pressures, flow rates of gases, or the like inside the reaction pipe 2 in each of processes are set to conditions according to a recipe as shown in FIG. 3, for example, as the controller 100 (the CPU 115) controls the heater controller 124 (the heaters 12), the MFC controller 125, the valve controller 126, or the like.

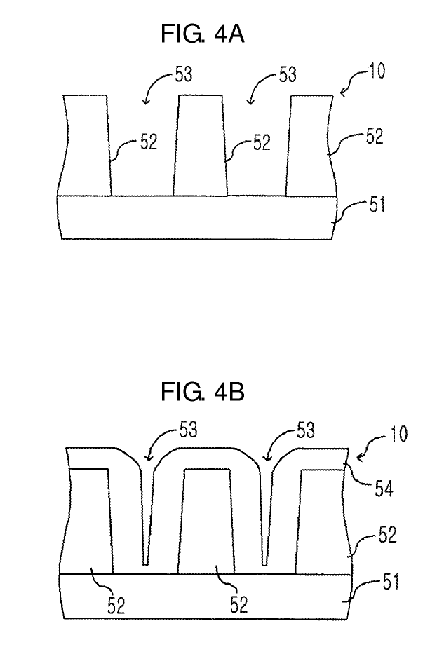

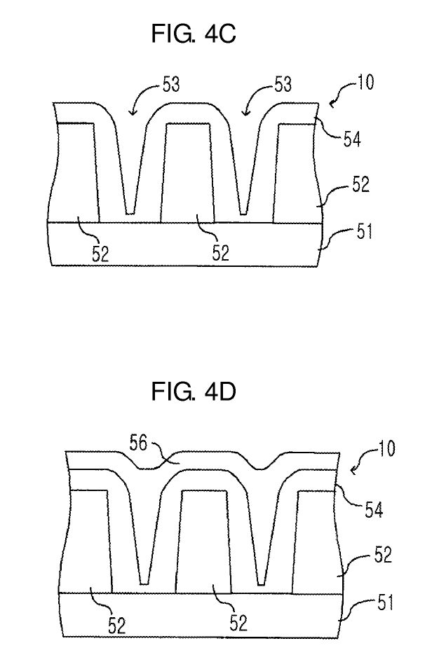

Furthermore, according to the present embodiment, in the semiconductor wafers 10 as objects to be processed, as shown in FIG. 4A, an insulation film 52 is formed on a substrate 51, and a groove 53 for providing a contact hole is provided on a surface of the semiconductor wafers 10. The silicon film formation method according to the present invention includes a first film formation operation for forming a silicon film (Si film), such as a polysilicon film, an amorphous silicon film, a polysilicon film doped with impurities, or an amorphous silicon film doped with impurities, or the like to fill the groove 53 provided on the semiconductor wafers 10, an etching operation for widening an opening of the groove 53 by etching the formed Si film, and a second film formation operation for forming a Si film to fill the groove 53 having the opening widened by the etching operation. Hereinafter, the silicon film formation method including the operations stated above will be described.

First, a temperature inside the reaction pipe 2 (the inner pipe 3) is set to a predetermined temperature, for example, 300° C., as shown in (a) of FIG. 3. Furthermore, as shown in (c) of FIG. 3, a predetermined amount of nitrogen is supplied into the inner pipe 3 (the reaction pipe 2) from the purge gas supply pipe 15. Next, the wafer boat 9, which holds the semiconductor wafers 10, as shown in FIG. 4A is arranged on the cover 7. Next, the semiconductor wafers 10 (wafer boat 9) is loaded into the reaction pipe 2 by moving up the cover 7 by using the boat elevator 8 (loading operation).

Next, as shown in (c) of FIG. 3, a predetermined amount of nitrogen is supplied into the inner pipe 3 from the purge gas supply pipe 15, and, at the same time, the temperature inside the reaction pipe 2 is set to a predetermined temperature, e.g., 535° C., as shown in (a) of FIG. 3. Furthermore, a gas inside the reaction pipe 2 is evacuated to depressurize the interior of the reaction pipe 2 to a predetermined pressure, for example, 93 Pa (0.7 Torr), as shown in (b) of FIG. 3. Next, the interior of the reaction pipe 2 is stabilized to the temperature and the pressure stated above (stabilizing operation).

Here, the temperature inside the reaction pipe 2 may be from 450° C. to 700° C., and may be preferably from 490° C. to 650° C. Furthermore, the pressure inside the reaction pipe 2 may be from 1.33 Pa to 133 Pa (from 0.01 Torr to 1 Torr). By setting the temperature and the pressure inside the reaction pipe 2 within the ranges stated above, a Si film may be formed more uniformly.

When the interior of the reaction pipe 2 is stabilized to the predetermined pressure and the predetermined temperature, supply of nitrogen from the purge gas supply pipe 15 is stopped. Next, as shown in (d) of FIG. 3, a predetermined amount of a film formation gas, for example, SiH₄, is supplied into the reaction pipe 2 from the process gas introduction pipe 13 (first film formation operation). In the first film formation operation, a Si film 54 is formed on the insulation film 52 on the semiconductor wafers 10 and on the groove 53 of the semiconductor wafers 10, as shown in FIG. 4B.

Here, in the first film formation operation, the Si film 54 may be formed on the insulation film 52 of the semiconductor wafers 10 and on the groove 53 of the semiconductor wafers 10, such that the groove 53 has an opening. In other words, in the first film formation operation, instead of forming the Si film 54 to completely fill the groove 53, the Si film 54 may be formed, such that the groove 53 has an opening. Therefore, occurrence of a void in the groove 53 during the first film formation operation may definitely be prevented.

When a predetermined amount of Si film is formed on the semiconductor wafers 10, supply of a film formation gas from the process gas introduction pipe 13 is stopped. Next, as shown in (c) of FIG. 3, a predetermined amount of nitrogen is supplied into the inner pipe 3 from the purge gas supply pipe 15, and, at the same time, the interior of the reaction pipe 2 is set to a predetermined temperature, for example, 300° C., as shown in (a) of FIG. 3. Furthermore, a gas inside the reaction pipe 2 is evacuated to depressurize the interior of the reaction pipe 2 to a predetermined pressure, for example, 40 Pa (0.3 Torr), as shown in (b) of FIG. 3. Next, the interior of the reaction pipe 2 is stabilized to the temperature and the pressure stated above (purge/stabilizing operation). Furthermore, to ensure exhaustion of a gas inside the reaction pipe 2, exhaustion of the gas inside the reaction pipe 2 and supply of nitrogen gas may be repeatedly performed for a plurality of times.

Here, the temperature inside the reaction pipe 2 may be from 100° C. to 550° C. If the temperature inside the reaction pipe 2 is below 100° C., the Si film 54 may not be etched in an etching operation described below. If the temperature inside the reaction pipe 2 is above 550° C., it may be difficult to control etching of the Si film 54. The pressure inside the reaction pipe 2 may be from 1.33 Pa to 133 Pa (from 0.01 Torr to 1 Torr).

When the interior of the reaction pipe 2 is stabilized to the predetermined pressure and the predetermined temperature, as shown in (c) of FIG. 3, a predetermined amount of nitrogen is supplied into the inner pipe 3 from the purge gas supply pipe 15, and, at the same time, as shown in (e) of FIG. 3, a predetermined amount of an etching gas, for example, Cl₂, is supplied into the reaction pipe 2 from the process gas introduction pipe 13 (etching operation). In the etching operation, as shown in FIG. 4C, the Si film 54 formed on the groove 53 of the semiconductor wafers 10 is etched.

In the etching operation, the Si film 54 formed in the first film formation operation is etched, such that the opening of the groove 53 is widened. In other words, as shown in FIG. 4C, an etching amount of a portion of the Si film 54 formed on the opening of the groove 53 is relatively great, whereas an etching amount of a portion of the Si film 54 formed near a bottom of the groove 53 is relatively low. Therefore, it may be easy to form the Si film 54 near the bottom of the groove 53 in a second film formation operation described below.

Furthermore, an etching gas may be Cl₂, with which it is easy to control etching of the Si film 54. In a case of using Cl₂ as an etching gas, the temperature inside the reaction pipe 2 may be from 250° C. to 300° C. Furthermore, the pressure inside the reaction pipe 2 may be from 1.33 Pa to 40 Pa (from 0.01 Torr to 0.3 Torr). By setting the temperature and the pressure inside the reaction pipe 2 within the ranges stated above, uniformity of an etching may be improved.

When the Si film 54 is etched as desired, supply of an etching gas from the process gas introduction pipe 13 is stopped. Next, as shown in (c) of FIG. 3, a predetermined amount of nitrogen is supplied into the inner pipe 3 from the purge gas supply pipe 15, and, at the same time, the interior of the reaction pipe 2 is set to a predetermined temperature, for example, 535° C., as shown in (a) of FIG. 3. Furthermore, a gas inside the reaction pipe 2 is evacuated to depressurize the interior of the reaction pipe 2 to a predetermined pressure, for example, 93 Pa (0.7 Torr), as shown in (b) of FIG. 3. Next, the interior of the reaction pipe 2 is stabilized to the temperature and the pressure stated above (purge/stabilizing operation). Furthermore, to ensure exhaustion of a gas inside the reaction pipe 2, exhaustion of the gas inside the reaction pipe 2 and supply of nitrogen gas may be repeatedly performed for a plurality of times.

When the interior of the reaction pipe 2 is stabilized to the predetermined pressure and the predetermined temperature, supply of nitrogen gas from the purge gas supply pipe 15 is stopped. Next, as shown in (d) of FIG. 3, a predetermined amount of a film formation gas, for example, SiH₄, is supplied into the reaction pipe 2 from the process gas introduction pipe 13 (second film formation operation). In the second film formation operation, as shown in (d) of FIG. 4, the Si film 56 is formed on the groove 53 of the semiconductor wafers 10.

Here, since the Si film 54 formed in the first film formation operation is etched in the etching operation such that the opening of the groove 53 widens, it is easy to form the Si film 56 near the bottom of the groove 53. Therefore, occurrence of a void in the groove 53 may be suppressed while the groove 53 is being filled with the Si film 56.

When a desired Si film is formed, supply of a film formation gas from the process gas introduction pipe 13 is stopped. Next, as shown in (c) of FIG. 3, a predetermined amount of nitrogen is supplied into the inner pipe 3 from the purge gas supply pipe 15, and, at the same time, the interior of the reaction pipe 2 is set to a predetermined temperature, for example, 300° C., as shown in (a) of FIG. 3. Furthermore, a gas inside the reaction pipe 2 is exhausted, so that the pressure inside the reaction pipe 2 is returned to a normal pressure (purge operation). Furthermore, to ensure exhaustion of a gas inside the reaction pipe 2, exhaustion of the gas inside the reaction pipe 2 and supply of nitrogen gas may be repeatedly performed for a plurality of times. Next, the semiconductor wafers 10 (the wafer boat 9) are unloaded from the reaction pipe 2 by moving down the cover 7 by using the boat elevator 8 (unloading operation). Therefore, formation of a silicon film is completed.

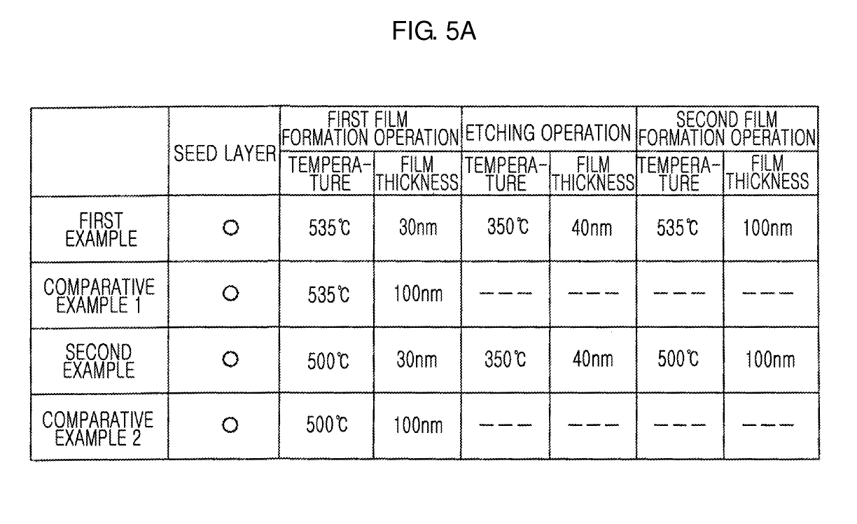

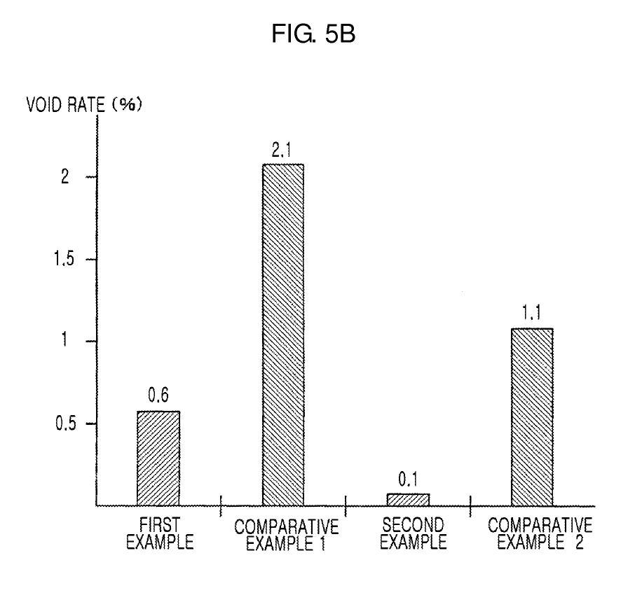

Next, to confirm effect of a silicon film formation method of performing an etching operation and a second film formation operation after a first film formation operation according to the present invention, a Si film is formed on the semiconductor wafer 10 shown in FIG. 4A based on a recipe shown in FIG. 3 except that the temperature inside the reaction pipe 2 is set to 350° C. during the etching operation, and a void rate in the Si film formed on the groove 53 is calculated (a first example of the present embodiment). The void rate is calculated by observing a Si film formed on the groove 53 using a SEM and dividing the volume of a void in the Si film formed on the groove 53 by a volume of a Si film which the groove 53 is filled with. Conditions for forming the Si film are shown in FIG. 5A, whereas the calculated void rate is shown in FIG. 5B. Furthermore, film thicknesses in FIG. 5A are a deposited film thickness of a beta substrate and an etched film thickness of a flat Si film. Furthermore, as shown in FIG. 5A, the temperature inside the reaction pipe 2 is set to 500° C. during the first film formation operation and the second film formation operation in a second example of the present embodiment. For comparison, even in the case where the etching operation and the second film formation operation are not performed, a silicon film is formed on the semiconductor wafer 10 and a void rate in a Si film formed on the groove 53 is calculated (comparative examples 1 and 2).

Furthermore, in the present example, a seed layer formation operation described below is performed prior to the first film formation operation. In the seed layer formation operation, a seed layer is formed by using DIPAS as a seed layer formation gas, setting the temperature inside the reaction pipe 2 to 400° C., and setting the pressure to 133 Pa (1 Torr).

As shown in FIG. 5B, a void rate in a Si film on the groove 53 is significantly reduced by performing the etching operation and the second film formation operation after the first film formation operation.

As described above, according to the present embodiment, after the first film formation operation in which a Si film is formed such that the groove 53 provided on the surface of the semiconductor wafers 10 has an opening, the etching operation for etching the Si film to widen the opening of the groove 53 and the second film formation operation for forming the Si film to fill the groove 53 are performed. Therefore, occurrence of a void in the groove 53 may be suppressed while the groove 53 is being filled with the Si film 56.

Furthermore, the present invention is not limited to the embodiment stated above, and various modifications and applications may be made therein. Hereinafter, other applicable embodiments of the present invention will be described.

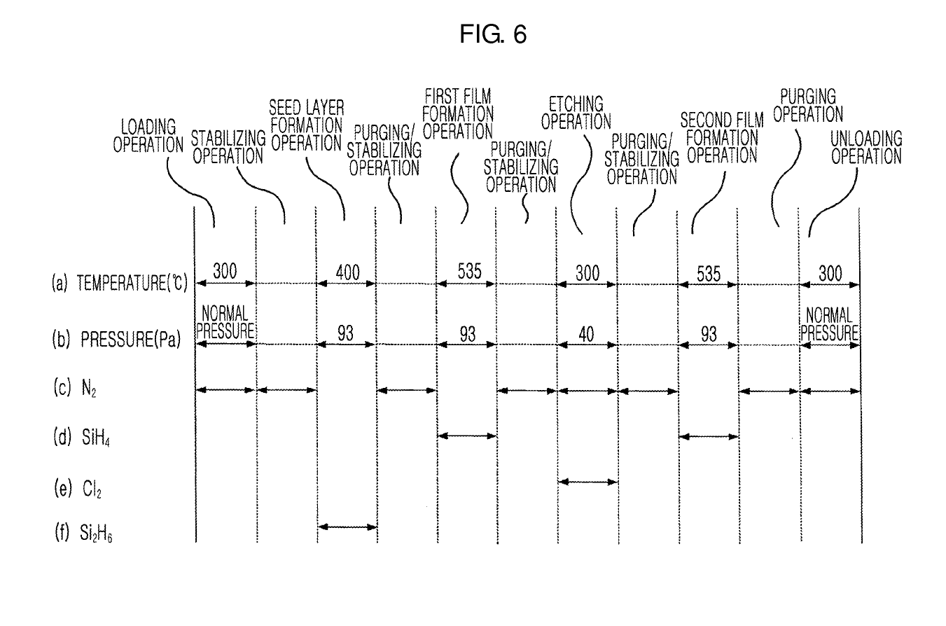

Although the first film formation operation, the etching operation, and the second film formation operation are performed in the above embodiment of the present invention, a seed layer formation operation for forming a seed layer on the insulation film 52 and the groove 53, for example, may be performed prior to the first film formation operation. A recipe for performing the seed formation operation is shown in FIG. 6.

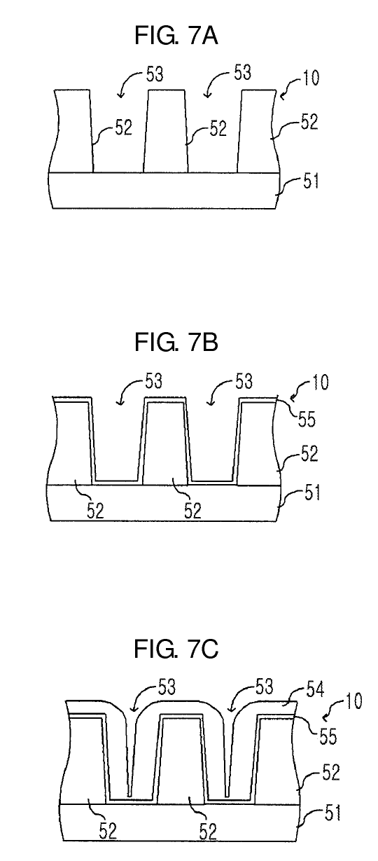

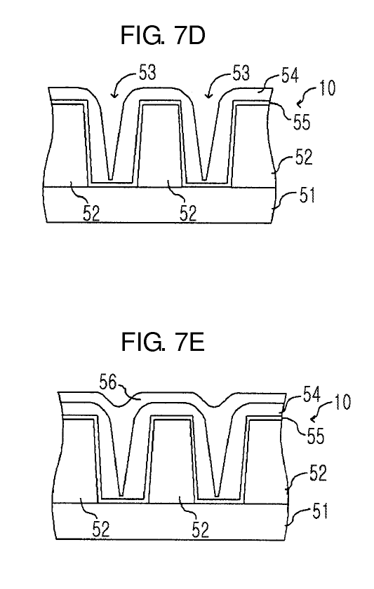

First, the temperature inside the reaction pipe 2 (the inner pipe 3) is set to a predetermined temperature, for example, 300° C., as shown in (a) of FIG. 6. Furthermore, as shown in (c) of FIG. 6, a predetermined amount of nitrogen is supplied into the inner pipe 3 (the reaction pipe 2) from the purge gas supply pipe 15. Next, the wafer boat 9, which holds the semiconductor wafers 10, as shown in FIG. 7A is arranged on the cover 7. Next, the semiconductor wafer 10 (wafer boat 9) is loaded into the reaction pipe 2 by moving up the cover 7 by using the boat elevator 8 (loading operation).

Next, as shown in (c) of FIG. 6, a predetermined amount of nitrogen is supplied into the inner pipe 3 from the purge gas supply pipe 15, and, at the same time, a temperature inside the reaction pipe 2 is set to a predetermined temperature, for example, 400° C., as shown in (a) of FIG. 6. Furthermore, a gas inside the reaction pipe 2 is evacuated to depressurize the interior of the reaction pipe 2 to a predetermined pressure, for example, 93 Pa (0.7 Torr), as shown in (b) of FIG. 6. Next, the interior of the reaction pipe 2 is stabilized to the temperature and the pressure stated above (stabilizing operation).

The temperature inside the reaction pipe 2 may be preferably from 350° C. to 500° C. Furthermore, in a case where a silane containing amino groups is used as a seed layer formation gas, the temperature inside the reaction pipe 2 may be more preferably from 350° C. to 450° C. The pressure inside the reaction pipe 2 may be from 1.33 Pa to 133 Pa (from 0.01 Torr to 1 Torr). By setting the temperature and the pressure inside the reaction pipe 2 within the ranges stated above, a seed film may be formed more uniformly.

When the interior of the reaction pipe 2 is stabilized to the predetermined pressure and the predetermined temperature, supply of nitrogen from the purge gas supply pipe 15 is stopped. Next, as shown in (f) of FIG. 6, a predetermined amount of a seed layer formation gas, for example, Si₂H₆, is supplied into the reaction pipe 2 from the process gas introduction pipe 13 (seed layer formation operation). In the seed layer formation operation, a seed layer 55 is formed on the insulation film 52 and the groove 53 of the semiconductor wafers 10, as shown in FIG. 7B. Since a high order silane, that is, Si₂H₆ is used as the seed layer formation gas in the present embodiment, the seed layer 55 may have a thickness from about 1 nm to about 2 nm. By forming the seed layer 55 to have a thickness from about 1 nm to about 2 nm, surface roughness of the Si film 54 to be formed on the seed layer 55 may be reduced. Furthermore, in the case of using a silane including amino groups as the seed layer formation gas, the seed layer 55 may be formed under conditions, which a film formation gas (source gas) is not thermally decomposed during film formation operations.

When the seed layer 55 having a desired thickness is formed on the semiconductor wafer 10, supply of a seed layer formation gas from the process gas introduction pipe 13 is stopped. Next, as shown in (c) of FIG. 6, a predetermined amount of nitrogen is supplied into the inner pipe 3 from the purge gas supply pipe 15, and, at the same time, the interior of the reaction pipe 2 is set to a predetermined temperature, for example, 535° C., as shown in (a) of FIG. 6. Furthermore, a gas inside the reaction pipe 2 is evacuated to depressurize the interior of the reaction pipe 2 to a predetermined pressure, for example, 93 Pa (0.7 Torr), as shown in (b) of FIG. 6. Next, the interior of the reaction pipe 2 is stabilized to the temperature and the pressure stated above (purge/stabilizing operation).

When the interior of the reaction pipe 2 is stabilized to the predetermined pressure and the predetermined temperature, supply of nitrogen from the purge gas supply pipe 15 is stopped. Next, as shown in (d) of FIG. 6, a predetermined amount of a film formation gas, for example, SiH₄, is supplied into the reaction pipe 2 from the process gas introduction pipe 13 (first film formation operation). In the first film formation operation, as shown in FIG. 7C, the Si film 54 is formed on the seed layer 55 of the semiconductor wafers 10.

Here, the Si film 54 is formed on the seed layer 55. Therefore, as described in the above embodiment, the surface roughness of the Si film 54 may be further reduced as compared to a case in which the Si film 54 is formed on two types of materials, which are the substrate 51 and the insulation film 52. As a result, occurrence of a void in the groove 53 may be further suppressed while the groove 53 is being filled with the Si film 54.

Furthermore, same as with the above embodiment, a purge/stabilizing operation, an etching operation (FIG. 7D), a purge/stabilizing operation, a second film formation operation (FIG. 7E), a purge operation, and an unloading operation are performed, and thus a silicon film formation method is completed.

As described above, the surface roughness of the formed Si film 54 may be reduced by performing the seed layer formation operation for forming a seed layer prior to the first film formation operation, and thus occurrence of a void in the groove 53 may be further suppressed while the groove 53 is being filled with the Si film 56.

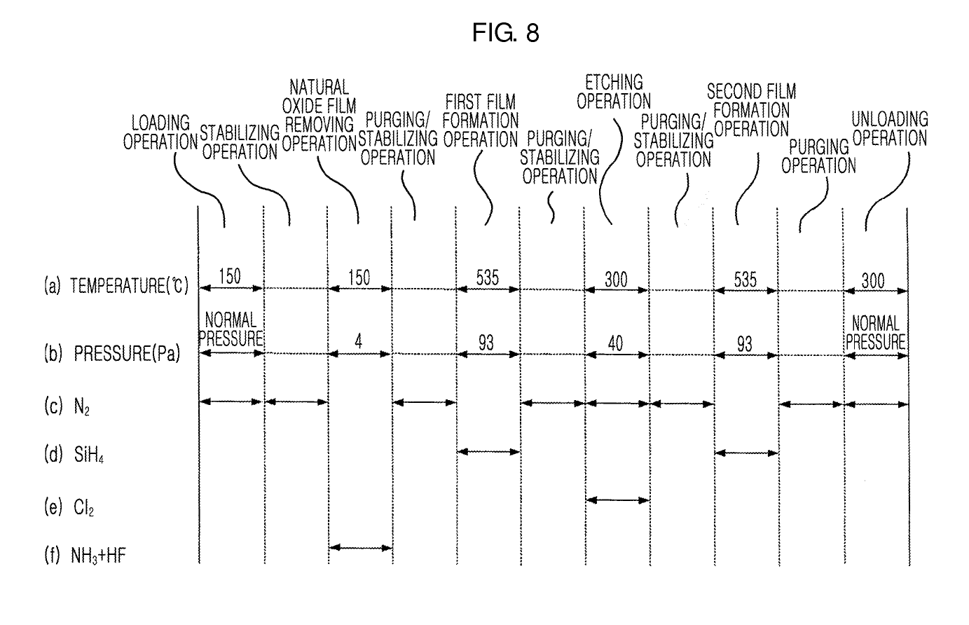

Furthermore, in the above embodiment, the first film formation operation, the etching operation, and the second film formation operation are performed. Alternatively, a natural oxide film removing operation for removing a natural oxide film formed on the bottom of the groove 53 may be performed prior to the first film formation operation. FIG. 8 shows a recipe for removing a natural oxide film. (refer to FIGS. 7A through 7E) Furthermore, in the present embodiment, ammonia (NH₃) and HF are used as natural oxide film removing gases.

First, the interior of the reaction pipe 2 (the inner pipe 3) is set to a predetermined temperature, for example, 150° C., as shown in (a) of FIG. 8. Furthermore, as shown in (c) of FIG. 8, a predetermined amount of nitrogen is supplied into the inner pipe 3 (reaction pipe 2) from the purge gas supply pipe 15. Next, the wafer boat 9, in which the semiconductor wafers 10 are held, is arranged on the cover 7. Next, the semiconductor wafers 10 (the wafer boat 9) are loaded into the reaction pipe 2 by moving up the cover 7 by using the boat elevator 8 (loading operation).

Next, as shown in (c) of FIG. 8, a predetermined amount of nitrogen is supplied into the inner pipe 3 from the purge gas supply pipe 15, and, at the same time, the temperature inside the reaction pipe 2 is set to a predetermined temperature, for example, 150° C., as shown in (a) of FIG. 8. Furthermore, a gas inside the reaction pipe 2 is evacuated to depressurize the interior of the reaction pipe 2 to a predetermined pressure, for example, 4 Pa (0.03 Torr), as shown in (b) of FIG. 8. Next, the interior of the reaction pipe 2 is stabilized to the temperature and the pressure stated above (stabilizing operation).

Here, the temperature inside the reaction pipe 2 may be from 25° C. to 200° C. The pressure inside the reaction pipe 2 may be from 0.133 Pa to 133 Pa (from 0.001 Torr to 1 Torr). By setting the temperature and the pressure inside the reaction pipe 2 within the ranges stated above, it may be easy to remove a natural oxide film. Furthermore, in the case of using ammonia and NF₃ as the natural oxide film removing gases, the temperature of the semiconductor wafer 100 may exceed 600° C.

When the interior of the reaction pipe 2 is stabilized to the predetermined pressure and the predetermined temperature, supply of nitrogen from the purge gas supply pipe 15 is stopped. Next, as shown in (f) of FIG. 8, a predetermined amount of ammonia (NH₃) and HF, is supplied into the reaction pipe 2 from the process gas introduction pipe 13 (natural oxide film removing operation). In the natural oxide film removing operation, a natural oxide film formed on the bottom of the groove 53 of the semiconductor wafer 10 may be removed.

When the natural oxide film is removed from the bottom of the groove 53 of the semiconductor wafer 10, supply of a natural oxide film removing gas from the process gas introduction pipe 13 is stopped. Next, as shown in (c) of FIG. 8, a predetermined amount of nitrogen is supplied into the inner pipe 3 from the purge gas supply pipe 15, and, at the same time, the interior of the reaction pipe 2 is set to a predetermined temperature, for example, 535° C., as shown in (a) of FIG. 8. Furthermore, a gas inside the reaction pipe 2 is evacuated to depressurize the interior of the reaction pipe 2 to a predetermined pressure, for example, 93 Pa (0.7 Torr), as shown in (b) of FIG. 8. Next, the interior of the reaction pipe 2 is stabilized to the temperature and the pressure stated above (purge/stabilizing operation). Furthermore, in the case where a natural oxide film is removed by using ammonia and HF, fluosilicate ammonium may remain on the substrate 51. However, since the temperature inside the reaction pipe 2 during the first film formation operation is 535° C., the fluosilicate ammonium sublimates.

When the interior of the reaction pipe 2 is stabilized to the predetermined pressure and the predetermined temperature, supply of nitrogen from the purge gas supply pipe 15 is stopped. Next, as shown in (d) of FIG. 8, a predetermined amount of a film formation gas, for example, SiH₄, is supplied into the reaction pipe 2 from the process gas introduction pipe 13 (first film formation operation). In the first film formation operation, the Si film 54 is formed on the insulation film 52 of the semiconductor wafer 10 and on the groove 53 of the semiconductor wafers 10.

Next, same as with the above embodiment, a purge/stabilizing operation, an etching operation, a purge/stabilizing operation, a second film formation operation, a purge operation, and an unloading operation are performed, and thus a silicon film formation is completed.

As described above, since the natural oxide film removing operation for removing a natural oxide film formed on the bottom of the groove 53 is performed prior to the first film formation operation, deterioration of properties of the formed Si film 56 as an electrode may be suppressed.

Furthermore, although the first film formation operation, the etching operation, and the second film formation operation are each performed once in the above embodiment of the present invention, the etching operation and the second film formation operation, for example, may be repeatedly performed for a plurality of times after the first film formation operation. Furthermore, even in a case where the seed layer formation operation or the natural oxide film removing operation is performed prior to the first film formation operation, the etching operation and the second film formation operation may be repeatedly performed for a plurality of times after the first film formation operation. In these cases, occurrence of a void in the groove 53 may be further suppressed while the groove 53 is being filled with the Si film 56.

Furthermore, the seed layer formation operation may be performed after the natural oxide film removing operation is performed, and then the first film formation operation, the etching operation, and the second film formation operation may be performed. In this case, occurrence of a void in the groove 53 may be further suppressed while the groove 53 is being filled with the Si film 56.

In the above embodiment, the Si film 54 is formed on the insulation film 52 of the semiconductor wafer 10 and on the groove 53 of the semiconductor wafer 10, such that the groove 53 has an opening in the first film formation operation. However, the Si film 54 may be formed, such that the groove 53 has no opening in the first film formation operation. In this case, the same effect as the above embodiment may be acquired by etching the Si film 54, such that the groove 53 has an opening in the etching operation.

Although SiH₄ is used as a film formation gas in the above embodiment, any gas may be used as long as a Si film, such as a polysilicon film, an amorphous silicon film, a polysilicon film doped with impurities or an amorphous silicon film doped with impurities, or the like may be formed by using the gas. For example, in a case of forming a polysilicon film doped with impurities or an amorphous silicon film doped with impurities, a gas containing impurities, such as PH₃, BCl₃, or the like, is used.

Although Cl₂ is used as an etching gas in the above embodiment, any gas may be used as long as a Si film formed in the first film formation operation may be etched by using the gas, and preferably, another halogen gas, such as F₂, ClF₃, or the like, may be used.

Although Si₂H₆ is used as a seed layer formation gas in the above embodiment, silane containing amino groups, or a high order silane including Si₄H₁₀, or the like may also be used, for example. For example, in a case of using silane containing amino groups, incubation time with respect to growth of a Si film may be reduced, or surface roughness of the Si film may be improved. Furthermore, although ammonia and HF are used as natural oxide film removing gases in the above embodiment, other gases, for example, ammonia and NF₃, or the like may be used as long as a natural oxide film on the bottom of the groove 53 may be removed by using the gas.

Although a batch type and vertical heat treatment apparatus having a double pipe structure is used as a heat treatment apparatus in the above embodiment, the present invention may also be applied to a batch type heat treatment apparatus having a single pipe structure, for example.

The controller 100 according to an embodiment of the present invention may be embodied by using a general computer system, rather than a dedicated system. For example, the controller 100 for implementing the processes described above may be constituted by installing a program for implementing the processes described above to a general purpose computer from a recording medium (a flexible disk, a CD-ROM, or the like) having the program recorded thereon.

Furthermore, the program may be distributed via any arbitrary means. Aside from distribution via a predetermined recording medium as stated above, the program may be distributed via a communication line, a communication network, a communication system, or the like, for example. In this case, the program may be posted to a bulletin board service (BBS) of a communication network, for example, and the program may be distributed to a carrier wave via a network. Furthermore, the processes described above may be implemented by launching the program distributed as described above and executing the program in the same manner as other application programs under the control of an OS.

The present invention may be useful for a silicon film formation method and a silicon film formation apparatus.

According to the present invention, occurrence of a void may be suppressed.

What is claimed is:

1. A silicon film formation method for forming a silicon film on a groove of an object to be processed, the groove being provided on a surface of the object to be processed, the silicon film formation method comprising:
forming a first silicon film to fill the groove of the object to be processed;
etching the first silicon film formed in the forming the first silicon film to widen an opening of the groove; and
forming a second silicon film on the groove having the opening widened in the etching the first silicon film to fill the groove.

2. The silicon film formation method of claim 1, further comprising holding a plurality of objects to be processed in a reaction chamber for holding the objects to be processed,
wherein the first and second silicon films are formed by supplying a silicon film formation gas into the reaction chamber in the forming the first silicon film and the forming the second silicon film, respectively, and
the first silicon film formed in the forming the first silicon film is etched by supplying an etching gas into the reaction chamber in the etching the first silicon film.

3. The silicon film formation method of claim 1, further comprising forming a seed layer on the surface of the object to be processed,
wherein the first silicon film is formed on the seed layer in the forming the first silicon film.

4. The silicon film formation method of claim 1, further comprising removing a natural oxide film formed on a bottom of the groove of the object to be processed.

5. The silicon film formation method of claim 1, wherein the etching the first silicon film and the forming the second silicon film are repeatedly performed for a plurality of times after the forming the first silicon film.

6. The silicon film formation method of claim 2, wherein, the forming the first silicon film, the etching the first silicon film, and the forming the second silicon film are continuously performed in a state where the object to be processed is held in the reaction chamber.

7. A silicon film formation apparatus for forming a silicon film on a groove of an object to be processed, the groove being provided on a surface of the object to be processed, the silicon film formation apparatus comprising:
a first film formation unit which forms a first silicon film to fill the groove of the object to be processed;
an etching unit which etches the first silicon film formed by the first film formation unit to widen an opening of the groove; and
a second film formation unit which forms a second silicon film on the groove having the opening widened by the etching unit to fill the groove.

8. The silicon film formation apparatus of claim 7, further comprising an holding unit which holds a plurality of objects to be processed in a reaction chamber for holding the objects to be processed,
wherein the first film formation unit and the second film formation unit form the first and second silicon films by supplying a silicon film formation gas into the reaction chamber, respectively, and
the etching unit etches the first silicon film formed by using the first film formation unit by supplying an etching gas into the reaction chamber.

9. The silicon film forming apparatus of claim 7, further comprising a seed layer formation unit which forms a seed layer on the surface of the object to be processed,
wherein the first film formation unit forms the first silicon film on the seed layer.

10. The silicon film formation apparatus of claim 7, further comprising a natural oxide film removing unit which removes a natural oxide film formed on a bottom of the groove of the object to be processed.

11. The silicon film formation apparatus of claim 8, further comprising a controller which controls each of components of the silicon film formation apparatus,
wherein the controller controls the first film formation unit, the etching unit, and the second film formation unit, such that, in a state where the object to be processed is held in the reaction chamber, the first silicon film is formed to fill the groove of the object to be processed, an opening of the groove is widened by etching the first silicon film, and the groove having the widened opening is filled with the second silicon film.
